(19) United States
(12) Patent Application Publication
(10) Pub. No.: US 2020/0369918 A1
(43) Pub. Date: Nov. 26, 2020

(54) POLISHING SOLUTION AND POLISHING METHOD

(71) Applicant: HITACHI CHEMICAL COMPANY, LTD., Tokyo (JP)

(72) Inventors: Shunsuke KONDO, Chiyoda-ku, Tokyo (JP); Keisuke INOUE, Chiyoda-ku, Tokyo (JP); Mayumi OUCHI, Chiyoda-ku, Tokyo (JP); Yuya OTSUKA, Chiyoda-ku, Tokyo (JP)

(21) Appl. No.: 16/636,965

(22) PCT Filed: Aug. 8, 2017
(86) PCT No.: PCT/JP2017/028793

§ 371 Date: Feb. 6, 2020

(51) Int. Cl. C09G 1/02; B24B 37/04; H01L 21/321; H01L 21/768

(52) U.S. Cl. CPC C09G 1/02; B24B 37/044; H01L 21/76877; H01L 21/7684; H01L 21/76843; H01L 21/3212

(57) ABSTRACT

Provided is a method for polishing an article including a Co-containing portion to be polished by a polishing liquid, in which the polishing liquid contains water, abrasive particles, and a metal dissolving agent, a pH of the polishing liquid is 6.0 or more, and a content of hydrogen peroxide in the polishing liquid is 0.0001% by mass or less based on the total mass of the polishing liquid.

### TECHNICAL FIELD

The present invention relates to a polishing method and a polishing liquid (polishing solution).

### BACKGROUND ART

In recent years, along with the progress in integration and functionality of semiconductor integrated circuits (Large-Scale Integration; hereinafter, referred to as “LSI”), new microfabrication techniques have been developed. A chemical mechanical polishing (hereinafter, referred to as “CMP”) method is one of such techniques. The CMP method is a technique that is frequently used in LSI manufacturing processes, particularly, in flattening of insulating films, formation of metal plugs, formation of buried wiring, and the like in multilayer wiring formation processes. This technique is disclosed, for example, in Patent Literature 1.

As a conductive substance that is a wiring material, copper (Cu) and a Cu-containing metal such a copper alloy that are low-resistance are used in order to increase the performance of LSI. Since microfabrication of a metal film containing Cu is difficult in a dry etching method that has been frequently used in formation of conventional aluminum (Al) alloy wiring, a so-called damascene method is mainly employed in formation of wiring containing Cu. In the damascene method, a conductive substance (for example, a Cu-containing metal) is deposited on a surface of an insulating film (for example, an interlayer insulating film) having grooves formed in advance on the surface, and a metal film is formed while the conductive substance is embedded in the grooves. Subsequently, a portion of the metal film other than the grooves in which the conductive substance is embedded is removed by the CMP method to form buried wirings. This technique is disclosed, for example, in Patent Literature 2.

Further, currently, in a plurality of use applications for contact materials, plug materials, via materials, gate materials, and the like, tungsten (W)-containing metals are used. In formation of contact plugs and the like, a process similar to the process used in formation of the wirings is employed.

Further, a liner (for example, a barrier layer) for preventing a conductive substance from being diffused into an insulating film is generally formed between the wiring and the insulating film and between the plug and the insulating film. As a metal constituting the liner that is a barrier layer, metals containing tantalum (Ta), titanium (Ti), and the like are used. The liner is formed, for example, by a method in which the metal material is deposited on the surface of the insulating film on which the grooves are formed to form a metal film, and then a portion of the metal film other than the grooves in which the conductive substance is embedded is removed by the CMP method. This technique is disclosed, for example, in Patent Literature 3.

Meanwhile, with miniaturization trend of semiconductor devices, a problem arises that defects such as voids (phenomena that local voids are generated) occur in wirings, plugs, and the like (for example, copper wirings, tungsten plugs, and the like) to cause a failure (for example, a wiring failure). In this regard, in order to solve the above-described problems by enhancing the embedding properties of the conductive substance, an attempt has been made in which a layer containing cobalt (Co) (a layer made of a cobalt-containing metal) is formed as a second liner between the liner, which is a barrier layer, and the wiring or the plug. This technique is disclosed, for example, in Patent Literature 4.

Further, the cobalt-containing metal is also studied as an alternative material for tungsten in a plurality of use applications for contact materials, plug materials, via materials, gate materials, and the like, because of its favorable embedding properties.

However, hydrogen peroxide (H₂O₂) may be contained in the polishing liquid used in the CMP method. This technique is disclosed, for example, in Patent Literature 5.

### CITATION LIST

### Patent Literature

Patent Literature 1: U.S. Pat. No. 4,944,836

Patent Literature 2: Japanese Unexamined Patent Publication No. H02-278822

Patent Literature 3: Japanese Unexamined Patent Publication No. 2001-85372

Patent Literature 4: Japanese Unexamined Patent Publication No. 2016-162761

Patent Literature 5: Japanese Unexamined Patent Publication No. 2009-239009

### SUMMARY OF INVENTION

### Technical Problem

However, as a result of studies of the present inventors, it becomes clear that in the case of polishing a portion to be polished of an article including a Co-containing portion to be polished using a conventional polishing liquid, when the pH of the polishing liquid is 6.0 or more, a stable polishing rate is difficult to obtain.

In this regard, an object of the present invention is to provide a polishing method with which a Co-containing portion to be polished can be polished at a stable polishing rate when an article including a Co-containing portion to be polished is polished even in the case of using a polishing liquid having a pH of 6.0 or more, and a polishing liquid used in the polishing method.

### Solution to Problem

The present inventors have speculated the reason why a stable polishing rate is not obtainable in the case of using a conventional polishing liquid as follows. That is, the present inventors have speculated that since Co is a metal that is easily oxidized as compared with a heavy metal such as Cu, an amount of hydrogen peroxide contained in the polishing liquid (hydrogen peroxide concentration) greatly influences a polishing rate, and a large difference in polishing rate of Co is caused by a slight difference in hydrogen peroxide concentration. The present inventors have completed the present invention based on such a speculation.

That is, an aspect of the present invention relates to a method for polishing an article including a Co-containing portion to be polished by a polishing liquid, in which the polishing liquid used in the method contains water, abrasive particles, and a metal dissolving agent, a pH of the polishing liquid is 6.0 or more, and a content of hydrogen peroxide in the polishing liquid is 0.0001% by mass or less based on the total mass of the polishing liquid.

According to the method, the Co-containing portion to be polished can be polished at a stable polishing rate. In the method, an excellent polishing rate of Co is easily obtained, and even in a case where the article includes a portion to be polished other than the Co-containing portion to be polished, the Co-containing portion to be polished is easily polished selectively. Further, in the method, the portion to be polished is hardly corroded.

Another aspect of the present invention relates to a polishing liquid used for polishing an article including a Co-containing portion to be polished, the polishing liquid containing water, abrasive particles, and a metal dissolving agent, in which a pH of the polishing liquid is 6.0 or more, and a content of hydrogen peroxide in the polishing liquid is 0.0001% by mass or less based on the total mass of the polishing liquid. According to the polishing liquid, the Co-containing portion to be polished can be polished at a stable polishing rate. Further, according to the polishing liquid, both an excellent polishing rate of Co and polishing selectivity are obtainable, and corrosion of the portion to be polished hardly occurs. Further, even in the case of long-term storage of the polishing liquid, polishing characteristics are hardly changed.

In an embodiment, the metal dissolving agent is an organic acid. According to the embodiment, the polishing rate of Co can be further improved.

In an embodiment, the metal dissolving agent contains at least one selected from the group consisting of dicarboxylic acids and amino acids. According to the embodiment, the polishing rate of Co can be further improved.

In an embodiment, a content of the abrasive particles is 0.01 to 20% by mass based on the total mass of the polishing liquid. In general, although a target polishing rate varies depending on a structure of a substrate, or the like, the polishing rate can be adjusted by adjusting the content of the abrasive particles. According to the embodiment, the polishing rate of Co is easily adjusted to a target polishing rate.

In an embodiment, the abrasive particles contain silica. According to the embodiment, defects such as scratches are hardly generated on the surface of the article after polishing.

In an embodiment, the polishing liquid further contains a metal corrosion inhibitor. According to the embodiment, the metal corrosion inhibitor generates a chelate complex with a metal such as Co so that excessive corrosion of the portion to be polished which is made of a metal material can be prevented. That is, the polishing liquid is more excellent in the effect of preventing the corrosion of the portion to be polished.

In an embodiment, the polishing liquid further contains a water-soluble polymer. According to the embodiment, flatness of the surface of the article after polishing can be improved.

In an embodiment, the polishing liquid further contains a pH adjusting agent. According to the embodiment, the pH of the polishing liquid is easily adjusted to a target value.

### Advantageous Effects of Invention

The present invention can provide a polishing method with which a Co-containing portion to be polished can be polished at a stable polishing rate when an article including a Co-containing portion to be polished is polished even in the case of using a polishing liquid having a pH of 6.0 or more, and a polishing liquid used in the polishing method.

### BRIEF DESCRIPTION OF DRAWINGS

FIG. 1 is a schematic cross-sectional view illustrating an example of a polishing method of an embodiment.

FIG. 2 is a schematic cross-sectional view illustrating an example of a polishing method of an embodiment.

FIG. 3 is a graph showing a relation between a hydrogen peroxide concentration in a polishing liquid and a polishing rate.

FIG. 4 is a graph showing a relation between a hydrogen peroxide concentration in a polishing liquid and a polishing rate.

FIG. 5 is a graph showing a relation between a hydrogen peroxide concentration in a polishing liquid and a polishing rate.

FIG. 6 is a graph showing a relation between a hydrogen peroxide concentration in a polishing liquid and a polishing rate.

FIG. 7 is a graph showing a relation between a hydrogen peroxide concentration in a polishing liquid and a polishing rate.

FIG. 8 is a graph showing a relation between a pH of a polishing liquid and a corrosion rate of Co.

### DESCRIPTION OF EMBODIMENTS

Hereinafter, preferred embodiments of the present invention will be described. However, the present invention is not limited to the following embodiments at all.

A polishing method of an embodiment is a method for polishing an article including a Co-containing portion to be polished by a polishing liquid. Further, the polishing liquid used in the polishing method of the present embodiment (hereinafter, referred to as the “polishing liquid of the present embodiment”) contains water, abrasive particles, and a metal dissolving agent, a pH of the polishing liquid is 6.0 or more, and a content of hydrogen peroxide in the polishing liquid (hydrogen peroxide concentration) is 0.0001% by mass or less based on the total mass of the polishing liquid.

In the polishing method of the present embodiment, an exposed surface (surface to be polished) of a portion to be polished is polished by the polishing liquid to remove the portion to be polished. That is, the polishing method of the present embodiment includes a step of polishing a surface to be polished of a Co-containing portion to be polished. Herein, at least a part of the surface to be polished contains Co. Incidentally, in the present specification, the expression “containing Co” means containing a cobalt atom, and although not limited to a cobalt simple substance, portions to be polished containing a cobalt alloy, an oxide of cobalt, an oxide of cobalt alloy, and the like are also included in the “Co-containing portion to be polished.” The same applies to the similar expressions such as “containing Cu” and “containing Ti.”

According to the polishing method of the present embodiment, the Co-containing portion to be polished can be polished at a stable polishing rate (removal rate). That is, a variation in polishing rate during polishing the Co-containing portion to be polished hardly occurs, and even in the case of performing the polishing method of the present embodiment a plurality of times, the portion to be polished can be polished constantly at a target polishing rate. The reason for this is speculated that, since the content of hydrogen peroxide in the polishing liquid is 0.0001% by mass or less, a variation in polishing rate of Co caused by a variation in hydrogen peroxide concentration in the polishing liquid, a slight difference in blending amount of hydrogen peroxide between polishing liquids, and the like is suppressed.

Further, as a result of the studies of the present inventors, in a case where the polishing liquid contains hydrogen peroxide, it became clear that there are tendencies that the hydrogen peroxide concentration may be decreased over time and the decrease amount of the hydrogen peroxide over time increases as the pH of the polishing liquid increases. Since the polishing liquid is not used in polishing immediately after the preparation depending on usage conditions, in a case where the pH of the polishing liquid containing hydrogen peroxide is in an alkaline region, a variation in hydrogen peroxide concentration easily occurs. This is also considered to be one of causes of a large variation in polishing rate in a case where the pH is 6.0 or more. On the other hand, since the polishing liquid of the present embodiment has a content of hydrogen peroxide of 0.0001% by mass or less, the polishing characteristics hardly change even in the case of long-term storage, and a stable polishing rate of Co is obtained.

Further, as a result of the studies of the present inventors, it becomes clear that in a case where the pH of the polishing liquid is 6.0 or more, when the hydrogen peroxide concentration is a certain value or more, the polishing rate of Co sharply decreases, while a polishing rate of a metal other than Co such as TiN increases. That is, it becomes clear that when a certain amount or more of hydrogen peroxide is contained in a case where the pH of the polishing liquid is 6.0 or more, a selection ratio of the polishing rate of Co and the polishing rate of the metal other than Co greatly varies and a favorable selection ratio is difficult to obtain. On the other hand, in the method, there are tendencies that an excellent polishing rate of Co is easily obtained, and even in a case where the article includes a portion to be polished other than the Co-containing portion to be polished, the Co-containing portion to be polished can be polished selectively. In the method of the present embodiment, particularly, a high selection ratio with respect to a Ti-containing metal such as a titania simple substance or titanium nitride, a silicon-based insulating material, or the like is easily obtainable.

Further, in a case where the portion to be polished contains Co, corrosion of the portion to be polished (corrosion of Co) tends to be a problem, but in the above-described method, the portion to be polished is hardly corroded from the reason of a pH being 6.0 or more, and the like.

The polishing method of the present embodiment may further include a step of polishing a surface to be polished of a portion to be polished other than the Co-containing portion to be polished. That is, the article used in the polishing method of the present embodiment may include a portion to be polished other than the Co-containing portion to be polished. However, the step of polishing a surface to be polished of a Co-containing portion to be polished and the step of polishing a surface to be polished of a portion to be polished other than the Co-containing portion to be polished are not clearly distinguished, and the case of simultaneously performing the respective steps is also included in the polishing method of the present embodiment. Further, in the case of separately performing the respective steps, the polishing liquid to be used may be the same or different.

Examples of the portion to be polished other than the Co-containing portion to be polished include a Cu-containing portion to be polished (for example, a portion to be polished containing copper, a copper alloy, an oxide of copper, an oxide of copper alloy, or the like), a W-containing portion to be polished (for example, a portion to be polished containing a tungsten simple substance, tungsten nitride, a tungsten alloy, or the like), a Ta-containing portion to be polished (for example, a portion to be polished containing a tantalum simple substance, tantalum nitride, a tantalum alloy, or the like), a Ti-containing portion to be polished (for example, a portion to be polished containing a titanium simple substance, titanium nitride, a titanium alloy, or the like), a Ru (ruthenium)-containing portion to be polished (for example, a portion to be polished containing a ruthenium simple substance, ruthenium nitride, a ruthenium alloy, or the like), and a portion to be polished containing a noble metal such as silver or gold. As described above, in the polishing method of the present embodiment, even in a case where the article further includes the portion to be polished as described above, there is a tendency that the Co-containing portion to be polished can be polished selectively. For example, in a case where the article includes a Ti-containing portion to be polished as the portion to be polished other than the Co-containing portion to be polished, a ratio of the polishing rate of the Co-containing portion to be polished to the polishing rate of the Ti-containing portion to be polished may be 1.0 or more.

The polishing method of the present embodiment is preferably performed by the CMP method. In the CMP method, the surface to be polished of the portion to be polished is polished by relatively moving a polishing platen and an article in a state where the surface of the article (the surface to be polished of the portion to be polished) is pressed against a polishing pad while the polishing liquid is supplied onto the polishing pad of the polishing platen.

In this case, as an apparatus used in polishing, a general polishing apparatus having a holder holding an article and a polishing platen which is connected to a motor or the like capable of changing the rotation speed and to which a polishing pad is attached can be used. The polishing pad is not limited in particular, but a general nonwoven fabric, foamed polyurethane, a porous fluororesin, and the like can be used.

Polishing conditions are not particularly limited. The rotational speed of the polishing platen is preferably 200 min⁻¹ or less in terms of the number of revolutions to prevent the article from flying off from the polishing platen. The pressing pressure of the article to the polishing pad is preferably 1 to 100 kPa and more preferably 5 to 50 kPa from the viewpoint of uniformizing the polishing rate in the surface to be polished (for example, the polishing rate of Co) and the viewpoint of obtaining sufficient flatness after polishing.

During the polishing, the polishing liquid can be continuously supplied between the polishing pad and the surface to be polished with a pump or the like. The supply amount is not limited, but it is preferable that the surface of the polishing pad is covered with the polishing liquid at all times.

In order to perform chemical mechanical polishing (CMP) with a consistent surface condition of the polishing pad, the polishing method of the present embodiment preferably further includes a conditioning step of conditioning the polishing pad before each polishing step. For example, the conditioning of the polishing pad is performed with a liquid containing at least water, while using a dresser to which diamond particles attach.

The polishing method of the present embodiment preferably further includes a washing step of washing the article after completion of polishing. In the washing step, for example, the article after completion of polishing is adequately washed in running water and is then dried after removing droplets, which have attached onto the article, with the use of a spin dry or the like.

The article used in the present embodiment is not particularly limited as long as it is an article including a Co-containing portion to be polished. The article may be, for example, a substrate such as a semiconductor substrate or a magnetic head.

Hereinafter, as an example of the polishing method of the present embodiment, a method of polishing an article including a substrate, a first portion to be polished, a second portion to be polished, and a third portion to be polished will be described in detail.

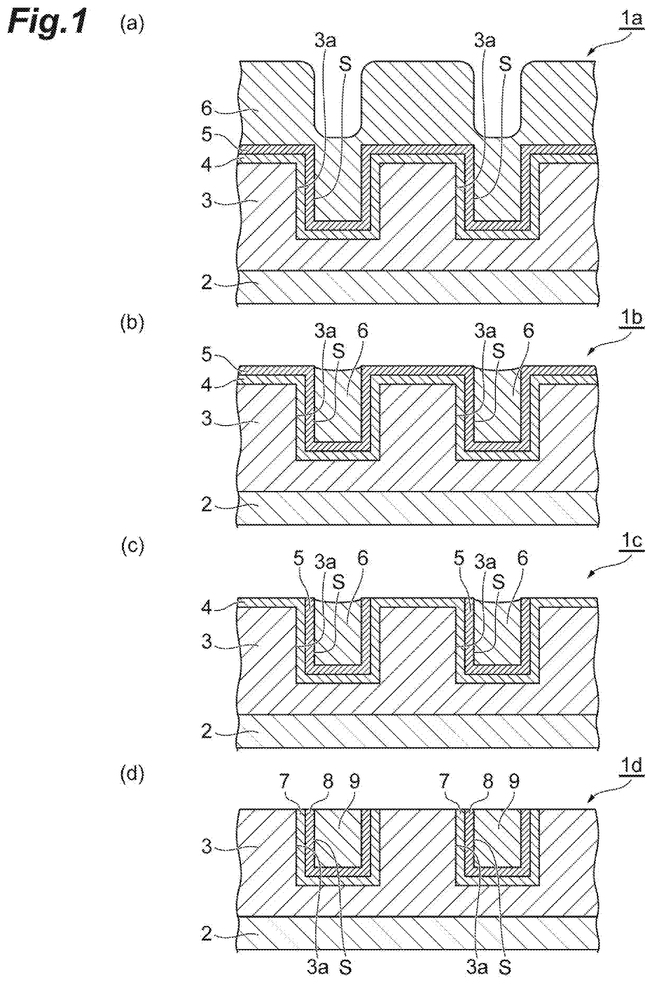

FIG. 1 is a schematic cross-sectional view illustrating an example of a polishing method of the present embodiment. An article 1a used in the polishing method of the present embodiment is a semiconductor substrate, and in the article 1a, an insulating portion 3, a first portion to be polished (Ti-containing portion to be polished) 4, a second portion to be polished (Co-containing portion to be polished) 5, and a third portion to be polished (Cu-containing portion to be polished) 6 are provided in this order on one surface of a substrate 2 such as a silicon substrate (see FIG. 1(a)).

The insulating portion 3 is provided on one surface of the substrate 2. The thickness of the insulating portion 3 is, for example, 0.01 to 2.0 μm.

The insulating portion 3 is formed from an insulating material. As a material forming the insulating portion 3, materials used in a silicon dioxide film, a silicon nitride film, a low-k film having a low dielectric constant, and the like can be widely used. Specific examples of materials forming the insulating portion 3 include a silicon-based insulating material (insulator) and an organic polymer-based insulating material (insulator). Examples of the silicon-based insulating material include silicon dioxide, silicon nitride, tetraethoxysilane, fluorosilicate glass, organosilicate glass obtained by using trimethylsilane or dimethoxydimethylsilane as a starting material, silicon oxynitride, silsesquioxane hydride, silicon carbide, and silicon nitride. Further, examples of the organic polymer-based insulating material include whole aromatic low permittivity insulating materials (insulators).

Groove portions 3a are formed in a predetermined pattern on a surface of the insulating portion 3 opposite to the substrate 2. The shape (width, depth, or the like) of the groove portions 3a is not particularly limited.

The insulating portion 3 is obtained in such a manner that a film is formed, for example, by a chemical vapor deposition (CVD) method, a spin coating method, a dip coating method, a spraying method, or the like, and then the surface of the insulating portion 3 is etched by a photolithography method or the like to form the groove portions 3a. As a specific example of the insulating portion 3, an interlayer insulating film in LSI manufacturing processes (particularly multilayer wiring formation processes) is exemplified.

The first portion to be polished 4 is a metal film formed on a surface of the insulating portion 3 opposite to the substrate 2 (a surface on which the groove portions 3a are formed). The first portion to be polished 4 is formed by a Ti-containing metal such as a Ti simple substance, titanium nitride (TiN), or a Ti alloy. The first portion to be polished 4 preferably contains Ti as a main component (for example, in 50 mol % or more), but may contain other elements that are inevitably mixed in film formation. The first portion to be polished 4 may be formed by one type of Ti-containing metal, or may be formed by a plurality of types of Ti-containing metal. The thickness of the first portion to be polished 4 is, for example, 0.01 to 2.5 μm.

The second portion to be polished 5 is a metal film formed on a surface of the first portion to be polished 4 opposite to the substrate 2. The second portion to be polished 5 is formed by a Co-containing metal such as a cobalt simple substance, a cobalt alloy, an oxide of cobalt, or an oxide of cobalt alloy. The second portion to be polished 5 preferably contains Co as a main component (for example, in 50 mol % or more), but may contain other elements that are inevitably mixed in film formation. The second portion to be polished 5 may be formed by one type of Co-containing metal, or may be formed by a plurality of types of Co-containing metal. The thickness of the second portion to be polished 5 is, for example, 0.01 to 2.5 μm.

The third portion to be polished 6 is a metal film formed on a surface of the second portion to be polished 5 opposite to the substrate 2, and fills spaces S in the groove portions 3a. The spaces S are spaces defined by portions (wall portions) formed on inner wall surfaces of the groove portions 3a of the second portion to be polished 5, and are spaces in which wiring portions are formed. The third portion to be polished 6 is formed by a Cu-containing metal such as a Cu simple substance, a Cu alloy, an oxide of Cu, or an oxide of Cu alloy. The third portion to be polished 6 preferably contains Cu as a main component (for example, in 50 mol % or more), but may contain other elements that are inevitably mixed in film formation. The third portion to be polished 6 may be formed by one type of Cu-containing metal, or may be formed by a plurality of types of Cu-containing metal. The thickness of the third portion to be polished 6 is, for example, 0.01 to 2.5 μm.

The first to third portions to be polished are formed by a sputtering method, a chemical vapor deposition (CVD) method, a plating method, or the like that is known.

In an example of FIG. 1, the surfaces to be polished of the first to third portions to be polished are polished by the polishing liquid to remove parts of the respective portions to be polished. Specifically, first, the surface of the article 1a (the exposed surface of the third portion to be polished 6) is polished by the polishing liquid to remove a part of the third portion to be polished (first polishing step). Thereby, the second portion to be polished 5 is exposed to obtain an article 1b (see FIG. 1(b)). It is preferable to finish the first polishing step at the time point at which a surface, which is parallel to the substrate 2, of the surfaces of the second portion to be polished 5 (for example, a surface other than the wall surfaces defining the spaces S) is entirely exposed. In the first polishing step, a part of the second portion to be polished 5 may be polished along with the third portion to be polished 6, but the first portion to be polished 4 is not exposed.

Next, the surface of the article 1b after the first polishing step (the exposed surfaces of the second portion to be polished 5 and the third portion to be polished 6) is polished by the polishing liquid to remove a part of the second portion to be polished 5 and a part of the third portion to be polished 6 (second polishing step). Thereby, the first portion to be polished 4 is exposed to obtain an article 1c (see FIG. 1(c)). It is preferable to finish the second polishing step at the time point at which a surface, which is parallel to the substrate 2, of the surfaces of the first portion to be polished 4 (for example, a surface other than the surface in contact with the wall portion of the second portion to be polished 5 defining the space S) is entirely exposed. In the second polishing step, a part of the first portion to be polished 4 may be polished along with the second portion to be polished 5 and the third portion to be polished 6, but the insulating portion 3 is not exposed.

Next, the surface of the article 1c after the second polishing step (the exposed surfaces of the first portion to be polished 4, the second portion to be polished 5, and the third portion to be polished 6) is polished by the polishing liquid to remove a part of the first portion to be polished 4, a part of the second portion to be polished 5, and a part of the third portion to be polished 6 (third polishing step). Thereby, the insulating portion 3 is exposed to obtain an article 1d (see FIG. 1(d)). It is preferable to finish the third polishing step at the time point at which a surface, which is parallel to the substrate 2, of the surfaces of the insulating portion 3 (for example, a surface other than the inner wall surface of the groove portion 3a) is entirely exposed. In the third polishing step, a part of the insulating portion 3 may be polished along with the first portion to be polished 4, the second portion to be polished 5, and the third portion to be polished 6.

The article 1d obtained by the above steps includes the substrate 2, the insulating portion 3, first liner portions 7, second liner portions 8, and wiring portions 9. In an example of FIG. 1, a part of the first portion to be polished is removed by polishing to form the first liner portion 7, a part of the second portion to be polished is removed by polishing to form the second liner portion 8, and a part of the third portion to be polished 6 is removed by polishing to form the wiring portion 9.

In the article 1d, the first liner portion 7 is formed on the inner wall surfaces of the groove portions 3a in the insulating portion 3. The first liner portions 7 in the article 1d are barrier layers having a function of preventing a Cu-containing metal, which is a conductive substance, from being diffused in the insulating portion 3.

In the article 1d, the second liner portions 8 are formed on the first liner portions 7. The second liner portions 8 in the article 1d contribute to enhancing the embedding property of the Cu-containing metal, which is a conductive substance, into the space S.

In the article 1d, the spaces S defined by the second liner portions 8 are filled with the Cu-containing metal, and the spaces filled with the metal form the wiring portions 9.

In the above-described polishing method, at least, the polishing liquid of the present embodiment is used in polishing of a Co-containing portion to be polished, but the polishing liquid of the present embodiment may be used in polishing of portions to be polished (first portion to be polished 4 and the third portion to be polished 6) other than the Co-containing portion to be polished. In other words, the polishing liquid in at least one of the second polishing step and the third polishing step is sufficient to be the polishing liquid of the present embodiment, and the polishing liquid in the first polishing step may be the polishing liquid of the present embodiment. However, as the polishing liquid used in the first polishing step, preferably, the polishing rate of the third portion to be polished is sufficiently higher than the polishing rate of the second portion to be polished, and a polishing liquid, which can selectively polish the third portion to be polished, is used. As such a polishing liquid, for example, a polishing liquid described in Japanese Patent No. 3337464 is exemplified.

Hereinbefore, an example of the polishing method of the present embodiment has been described with reference to FIG. 1, but the polishing method of the present embodiment is not limited to the above-described example.

In the above-described example, the second portion to be polished is the Co-containing portion to be polished, but a portion to be polished (at least one of the first portion to be polished and the third portion to be polished) other than the second portion to be polished may be a Co-containing portion to be polished. In this case, the second portion to be polished may be formed by a Ta-containing metal such as a tantalum simple substance, tantalum nitride, or an tantalum alloy; a Ti-containing metal such as titanium simple substance, titanium nitride, or a titanium alloy; a W-containing metal such as tungsten simple substance, tungsten nitride, or a tungsten alloy; a Ru-containing metal such as ruthenium simple substance, ruthenium nitride, or a ruthenium alloy; or the like. Further, in the case of using an article in which the third portion to be polished is a Co-containing portion to be polished, the wiring portion 9 in the article 1d may be a plug portion such as a contact plug. That is, a plug portion may be formed by removing a part of the third portion to be polished by polishing.

Further, in the above-described example, the first portion to be polished is formed by a Ti-containing metal, but the second portion to be polished may be formed by a Ta-containing metal, a W-containing metal, a Ru-containing metal, or the like.

Further, in the above-described example, the third portion to be polished is formed by a Cu-containing metal, but the third portion to be polished may be formed by a noble metal such as silver or gold, a W-containing metal, or the like.

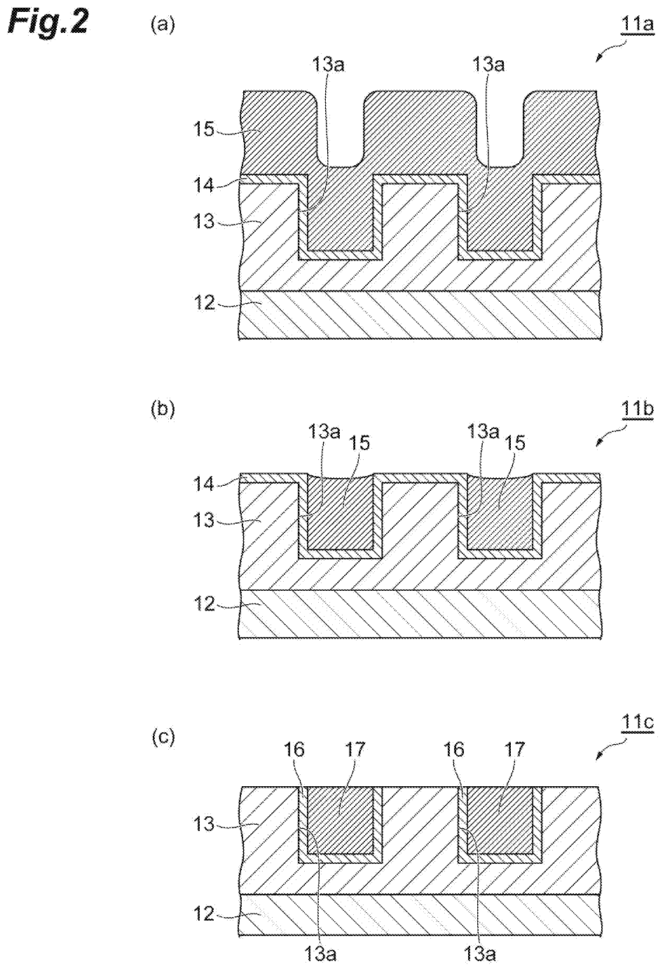

Further, in the above-described example, the number of the portions to be polished of the article is three, but the number of portions to be polished is not particularly limited as long as an article includes a Co-containing portion to be polished. For example, as illustrated in FIG. 2, an article 11a having two portions to be polished may be used.

The article 11a includes a substrate 12, an insulating portion 13 in which groove portions 13a are formed, a first portion to be polished 14, and a second portion to be polished 15 (see FIG. 2(a)). In the article 11a, the first portion to be polished 14 and the second portion to be polished 15 are provided in this order on one surface of the substrate 12. In an example illustrated in FIG. 2, the first portion to be polished 14 and the second portion to be polished 15 can be polished in the same manner as in the above-described example. For example, first, the surface of the article 11a (the exposed surface of the second portion to be polished 15) is polished by the polishing liquid to remove a part of the second portion to be polished (first polishing step). Thereby, the first portion to be polished 14 is exposed to obtain an article 11b (see FIG. 2(b)). Next, the surface of the article 11b after polishing (the exposed surfaces of the first portion to be polished 14 and the second portion to be polished 15) is polished by the polishing liquid to remove a part of the first portion to be polished 14 and a part of the second portion to be polished 15 (second polishing step). Thereby, the insulating portion 13 is exposed (see FIG. 2(c)). Thereby, an article 11c including the insulating portion 13, liner portions 16, and wiring portions 17 is obtained.

In this example, at least one of the first portion to be polished 14 and the second portion to be polished 15 is a Co-containing portion to be polished, and the polishing liquid of the present embodiment is used in at least one of the first polishing step and the second polishing step. Incidentally, the wiring portion 17 may be a plug portion. Further, the first portion to be polished 14 may be formed by the same material as those of the first portion to be polished 4 and the second portion to be polished 5 in the above-described example, and the second portion to be polished 15 may be formed by the same material as that of the third portion to be polished 6 in the above-described example.

Next, the details of the polishing liquid of the present embodiment will be described.

(Water)

As the water contained in the polishing liquid, ion-exchanged water (deionized water), pure water, ultrapure water, distilled water, and the like can be used. In order to prevent the action of other components contained in the polishing liquid from being inhibited as much as possible, the total content of transition metal ions in water to be used is preferably 100 ppb or less. In the present embodiment, water whose purity is increased by operations such as removal of impurity ions by an ion-exchange resin, removal of foreign substances by a filter, and distillation may be used.

(Abrasive Particles)

Abrasive particles (abrasive grains) contain one or more types of particles. Incidentally, in the present specification, the “abrasive particles” mean an aggregation of a plurality of particles, and for convenience, one particle constituting the abrasive particles may be referred to as an abrasive particle.

Examples of constituent materials of abrasive particles include inorganic substances such as silica, alumina, zirconia, ceria, titania, germania, and silicon carbide; organic substance such as polystyrene, polyacrylic acid, and polyvinyl chloride; and modified substances thereof. Examples of abrasive particles containing the modified substances include modified substances in which the surfaces of the abrasive particles containing silica, alumina, ceria, titania, zirconia, germania, or the like are modified with an alkyl group.

The abrasive particles preferably contain silica from the viewpoint that defects such as scratches are hardly generated on the surface of the article after polishing (for example, a surface of a wiring portion, a surface of a liner portion, a surface of an insulating portion, or the like). The abrasive particles may be formed from only particles containing silica. Examples of the abrasive particles containing silica include amorphous silica, crystalline silica, molten silica, spherical silica, synthetic silica, hollow silica, and colloidal silica.

The average secondary particle diameter of the abrasive particles is preferably 120 nm or less, more preferably 100 nm or less, further preferably 90 nm or less, and particularly preferably 80 nm or less. When the average secondary particle diameter of the abrasive particles is 120 nm or less, the polishing liquid tends to be more excellent in the polishing rate of Co. Further, the average secondary particle diameter of the abrasive particles is preferably 5 nm or more, more preferably 10 nm or more, and further preferably 15 nm or more. When the average secondary particle diameter of the abrasive particles is 5 nm or more, the polishing liquid tends to be more excellent in the polishing rate of Co. From these viewpoints, the average secondary particle diameter of the abrasive particles is preferably 5 to 120 nm, more preferably 5 to 100 nm, further preferably 10 to 90 nm, and particularly preferably 15 to 80 nm. The average secondary particle diameter of the abrasive particles is measured using a light diffraction scattering particle size distribution meter (for example, N5 manufactured by Beckman Coulter, Inc.).

The content of the abrasive particles is preferably 0.01% by mass or more, more preferably 0.05% by mass or more, and further preferably 0.1% by mass or more, based on the total mass of the polishing liquid. When the content of the abrasive particles is 0.01% by mass or more, the ability to remove Co-containing metals becomes sufficient, and the polishing rate of Co tends to be sufficient. The content of the abrasive particles is preferably 20% by mass or less, more preferably 15% by mass or less, and further preferably 10% by mass or less, based on the total mass of the polishing liquid. When the content of the abrasive particles is 20% by mass or less, favorable dispersion stability of the abrasive particles is easily obtained, and defects such as scratches hardly occur. From these viewpoints, the content of the abrasive particles is preferably 0.01 to 20% by mass, more preferably 0.05 to 15% by mass, and further preferably 0.1 to 10% by mass, based on the total mass of the polishing liquid.

(Metal Dissolving Agent)

The metal dissolving agent has a function of dissolving metals (such as metal oxides). The metal dissolving agent is, for example, a metal oxide dissolving agent. As the metal dissolving agent, those known as the metal oxide dissolving agent can be used, and for example, an organic acid, an organic acid ester, an organic acid salt, an inorganic acid, an inorganic acid salt, and the like can be used. The metal dissolving agent preferably has water solubility.

Specific examples of the metal dissolving agent including organic acids such as monocarboxylic acids such as acetic acid, propionic acid, and benzoic acid, dicarboxylic acids such as malonic acid, succinic acid, citric acid, malic acid, oxalic acid, tartaric acid, picolinic acid, phthalic acid, adipic acid, and glutaric acid, and amino acids such as alanine, glycine, leucine, isoleucine, asparagine, aspartic acid, arginine, and cysteine; organic acid esters thereof and organic acid salts thereof (for example, ammonium salt); inorganic acids such as sulfuric acid, nitric acid, phosphoric acid, and hydrochloric acid; and inorganic acid salts thereof. These metal dissolving agents may be used singly or as a mixture of two or more types thereof.

The metal dissolving agent is preferably an organic acid and more preferably at least one selected from the group consisting of dicarboxylic acids and amino acids, from the viewpoint of further improving the polishing rate of Co. Examples of preferred dicarboxylic acids from the viewpoint of further improving the polishing rate of Co include malic acid, citric acid, succinic acid, malonic acid, diglycol acid, isophthalic acid, and methylsuccinic acid. Examples of preferred amino acids from the viewpoint of further improving the polishing rate of Co include glycine, asparagine, aspartic acid, arginine, isoleucine, and threonine.

The content of the metal dissolving agent is preferably 0.005% by mass or more, more preferably 0.01% by mass or more, further preferably 0.05% by mass or more, and particularly preferably 0.1% by mass or more, based on the total mass of the polishing liquid. When the content of the metal dissolving agent is 0.005% by mass or more, the polishing rate of Co can be further improved. The content of the metal dissolving agent is preferably 4% by mass or less, more preferably 3% by mass or less, further preferably 2% by mass or less, and particularly preferably 1.3% by mass or less, based on the total mass of the polishing liquid. When the content of the metal dissolving agent is 4% by mass or less, the abrasive particles hardly aggregate, and the storage stability of the polishing liquid can be further improved. As a result, a more stable polishing rate tends to be obtained. From these viewpoints, the content of the metal dissolving agent is preferably 0.005 to 4% by mass, more preferably 0.01 to 3% by mass, further preferably 0.05 to 2% by mass, and particularly preferably 0.1 to 1.3% by mass.

(Hydrogen Peroxide)

The content of the hydrogen peroxide in the polishing liquid is 0.0001% by mass or less based on the total mass of the polishing liquid. The content of the hydrogen peroxide is measured using a potentiometric automatic titrator COM2500 manufactured by HIRANUMA SANGYO Co., Ltd. by the method described in Examples. The value of 0.0001% by mass is a detection limit value of hydrogen peroxide which can be detected by the method described in Examples.

(pH Adjusting Agent)

The polishing liquid of the present embodiment may further contain a pH adjusting agent for adjusting the pH to a target pH. Examples of the pH adjusting agent include hydroxides of alkali metal ions; hydroxides of alkaline-earth metals; and ammonia. As the pH adjusting agent, from the viewpoint of preventing the agglomeration of the abrasive particles, potassium hydroxide, benzylamine, and diethanolamine are preferred, and potassium hydroxide is more preferred. The pH adjusting agent may be used singly or in combination of two or more types thereof.

The content of the pH adjusting agent is preferably 5% by mass or less, more preferably 3% by mass or less, and further preferably 2% by mass or less, based on the total mass of the polishing liquid, from the viewpoint of preventing the agglomeration of the abrasive particles. The lower limit of the content of the pH adjusting agent is not particularly limited, and may be, for example, 0% by mass.

(Metal Corrosion Inhibitor)

The polishing liquid of the present embodiment may further contain a metal corrosion inhibitor. The metal corrosion inhibitor is a compound capable of forming a protective film for preventing excessive corrosion of a portion to be polished which is made of a metal material on a surface of the portion to be polished, by generating a chelate complex with a metal such as Co. As for such a compound, a known compound can be used as the metal corrosion inhibitor. Examples of the metal corrosion inhibitor include a compound having a triazole skeleton, a compound having an imidazole skeleton, a compound having a pyrimidine skeleton, a compound having a guanidine skeleton, a compound having a thiazole skeleton, and a compound having a pyrazole skeleton.

Examples of the compound having a triazole skeleton include 1,2,3-triazole, benzotriazole, 1-hydroxybenzotriazole, bis[(1-benzotriazolyl)methyl]phosphonic acid, and 5-methylbenzotriazole. Examples of the compound having an imidazole skeleton include 2-methylimidazole and 2-aminoimidazole. Examples of the compound having a pyrimidine skeleton include pyrimidine and 1,2,4-triazolo[1,5-a]pyrimidine. Examples of the compound having a guanidine skeleton include 1,3-diphenylguanidine and 1-methyl-3-nitroguanidine. Examples of the compound having a thiazole skeleton include 2-mercaptobenzothiazole and 2-aminothiazole. Examples of the compound having a pyrazole skeleton include 3,5-dimethylpyrazole, 3-methyl-5-pyrazolone, and 3-amino-5-methylpyrazole. Among these, from the viewpoint of suppressing the corrosion of the portion to be polished, the compound having a triazole skeleton is preferred. Furthermore, among the compounds having a triazole skeleton, 1,2,3-triazole, 1,2,4-triazole, 3-amino-1H-1,2,4-triazole, 4-amino-4H-1,2,4-triazole, benzotriazole, 1-hydroxybenzotriazole, and 5-methylbenzotriazole are more preferred. These metal corrosion inhibitors may be used singly or in combination of two or more types thereof.

The content of the metal corrosion inhibitor is preferably 0.0005% by mass or more, more preferably 0.001% by mass or more, and further preferably 0.003% by mass or more, based on the total mass of the polishing liquid, from the viewpoint that corrosion of the portion to be polished can be easily suppressed. The content of the metal corrosion inhibitor is preferably 0.5% by mass or less, more preferably 0.3% by mass or less, and further preferably 0.1% by mass or less, based on the total mass of the polishing liquid, from the viewpoint that corrosion of the portion to be polished can be easily suppressed. From these viewpoints, the content of the metal corrosion inhibitor is preferably 0.0005 to 0.5% by mass, more preferably 0.001 to 0.3% by mass, and further preferably 0.003 to 0.1% by mass, based on the total mass of the polishing liquid.

(Water-Soluble Polymer)

The polishing liquid of the present embodiment may further contain a water-soluble polymer. Herein, the “water-soluble polymer” is defined as a polymer that is dissolved in an amount of 0.1 g or more with respect to 100 g of water at 25° C. When the polishing liquid contains a water-soluble polymer, the flatness of the surface of the article after polishing can be improved.

The water-soluble polymer is not particularly limited as long as it is a polymer which is miscible with water, and for example, a polymer compound having a structure represented by the following Formula (1) is exemplified.

RO—(X—O)n-(Y—O)m-H (1)

[in the formula, R represents an alkyl group, an alkenyl group, a phenyl group, a polycyclic phenyl group, an alkylphenyl group, or an alkenylphenyl group, X represents an ethylene group which may have a substituent, Y represents a propylene group which may have a substituent, and n and m each represent an integer of 0 or more. n represents the number of repetitions of the ethylene group, and m represents the number of repetitions of the propylene group.]

The number of carbon atoms of R is preferably 6 or more and preferably 30 or less. Examples of the substituents which X and Y have (functional groups substituting at least one of hydrogen atoms which the ethylene group and the propylene group have) include an alkyl group and a phenyl group. In Formula (1), n+m may be 4 or more.

Among the compounds represented by Formula (1), from the viewpoint of further improving flatness after polishing, a compound in which the number of carbon atoms of R in Formula (1) is 6 or more and n+m is 4 or more is preferred.

Specific examples of the compounds represented by Formula (1) include polyoxyethylene alkyl ethers such as polyoxyethylene lauryl ether, polyoxyethylene cetyl ether, polyoxyethylene stearyl ether, and polyoxyethylene oleyl ether, polyoxyethylene phenyl ethers such as polyoxyethylene octylphenyl ether and polyoxyethylene nonylphenyl ether, and alkyl ethers of a copolymer of polyoxypropylene and polyoxyethylene such as polyoxyethylene polyoxypropylene octyl ether.

Examples of other water-soluble polymers include water-soluble polymers having a carboxylic acid group or a carboxylate group. Examples of such water-soluble polymers include a homopolymer of a monomer having a carboxylic acid group such as acrylic acid, methacrylic acid, or maleic acid; and a homopolymer in which the moiety of the carboxylic acid group of the polymer becomes a carboxylate group such as an ammonium salt. Specifically, polyacrylic acid and polymers in which at least a part of a carboxylic acid group of polyacrylic acid is substituted with a carboxylic acid ammonium salt group are exemplified. Further, examples of other water-soluble polymers include polysaccharides such as alginic acid, pectic acid, and hydroxyethyl cellulose; polycarboxylic acid such as polyaspartic acid and polyglutamic acid and a salt thereof; and vinyl-based polymers such as polyvinyl alcohol, polyvinylpyrrolidone, and polyacrolein and a copolymer thereof. The water-soluble polymers may be used singly or in combination of two or more types thereof.

The weight average molecular weight of the water-soluble polymer is preferably 100 or more, more preferably 200 or more, and further preferably 300 or more, from the viewpoint that the effect of improving flatness after polishing can be expected. The weight average molecular weight of the water-soluble polymer is preferably 500,000 or less, more preferably 100,000 or less, and further preferably 50,000 or less, form the viewpoint of maintaining favorable storage stability of the polishing liquid. From these viewpoints, the weight average molecular weight of the water-soluble polymer is preferably 100 to 500,000, more preferably 200 to 100,000, and further preferably 300 to 50,000.

The weight average molecular weight (Mw) of the water-soluble polymer can be measured, for example, using gel permeation chromatography (GPC) under the following conditions.

### [Conditions]

Sample: 20 μL

Standard polyethylene glycol: Standard polyethylene glycol (molecular weight: 106, 194, 440, 600, 1,470, 4,100, 7,100, 10,300, 12,600, and 23,000) manufactured by Polymer Laboratories Co., Ltd.

Detector: RI-monitor, trade name “Syodex-RI SE-61” manufactured by Showa Denko K.K.

Pump: trade name “L-6000” manufactured by Hitachi, Ltd.

Column: trade names “GS-220 HQ” and “GS-620 HQ” manufactured by Showa Denko K.K. were connected in this order and used.

Eluent: 0.4 mol/L of sodium chloride aqueous solution or tetrahydrofuran

Measurement temperature: 30° C.

Flow rate: 1.00 mL/min

Measurement time: 45 min

The content of the water-soluble polymer is preferably 0.0005% by mass or more, more preferably 0.0008% by mass or more, and further preferably 0.001% by mass or more, based on the total mass of the polishing liquid. When the content of the water-soluble polymer is 0.0005% by mass or more, the effect of improving flatness after polishing is easily obtainable. The content of the water-soluble polymer is preferably 0.5% by mass or less, more preferably 0.3% by mass or less, further preferably 0.2% by mass or less, based on the total mass of the polishing liquid. When the content of the water-soluble polymer is 0.5% by mass or less, the agglomeration of the abrasive particles can be prevented and storage stability can be further improved. From these viewpoints, the content of the water-soluble polymer is preferably 0.0005 to 0.5% by mass, more preferably 0.0008 to 0.3% by mass, and further preferably 0.001 to 0.2% by mass, based on the total mass of the polishing liquid.

(Bactericidal Agent)

The polishing liquid of the present embodiment may further contain a bactericidal agent for suppressing biological contamination. Examples of the bactericidal agent include 2-methyl-4-isothiazoline-3-one and 5-chloro-2-methyl-4-isothiazoline-3-one. The bactericidal agent is suitably used for maintaining polishing characteristics.

(Organic Solvent)

The polishing liquid of the present embodiment may further contain an organic solvent. When the polishing liquid contains an organic solvent, wettability of the polishing liquid with respect to a metal-containing portion to be polished (for example, a portion to be polished which is provided in the vicinity of the Co-containing portion to be polished) can be improved. The organic solvent may be used singly or in combination of two or more types thereof.

The organic solvent is not particularly limited, but a solvent which can be mixed with water is preferred. From such a viewpoint, as the organic solvent, a solvent which is dissolved in an amount of 0.1 g or more with respect to 100 g of water at 25° C. is more preferred.

Specific examples of the organic solvent include carbonate esters such as ethylene carbonate and propylene carbonate; lactones such as butyl lactone and propyl lactone; glycols such as ethylene glycol, propylene glycol, and diethylene glycol; derivatives of glycols; ethers (excluding derivatives of glycols) such as tetrahydrofuran and dioxane; alcohols (monoalcohols) such as methanol, ethanol, propanol, 3-methoxy-3-methylbutanol; ketones such as acetone and methyl ethyl ketone; amides such as dimethylformamide and N-methylpyrrolidone; esters (excluding carbonate esters and lactones) such as ethyl acetate and ethyl lactate; and sulfolanes such as sulfolane.

Examples of the derivatives of glycols include glycol monoethers such as ethylene glycol monomethyl ether and propylene glycol monomethyl ether; and glycol ethers such as ethylene glycol dimethyl ether and propylene glycol dimethyl ether.

As the organic solvent, at least one selected from the group consisting of glycols, derivatives of glycols, alcohols, and carbonic acid esters is preferred, and alcohols are more preferred.

The content of the organic solvent is preferably 0.1% by mass or more, more preferably 0.2% by mass or more, further preferably 0.5% by mass or more, particularly preferably 1% by mass or more, and extremely preferably 1.2% by mass or more, based on the total mass of the polishing liquid, from the viewpoint of obtaining favorable wettability with respect to the metal-containing portion to be polished. Further, the content of the organic solvent is preferably 95% by mass or less, more preferably 50% by mass or less, further preferably 10% by mass or less, particularly preferably 5% by mass or less, extremely preferably 3% by mass or less, very preferably 2% by mass or less, and even more preferably 1.5% by mass or less, based on the total mass of the polishing liquid, from the viewpoint of preventing the possibility of ignition to enable the production process to be implemented safely. From these viewpoints, the content of the organic solvent is preferably 0.1 to 95% by mass, more preferably 0.2 to 50% by mass, further preferably 0.5 to 10% by mass, particularly preferably 1 to 5% by mass, extremely preferably 1.2 to 3% by mass, very preferably 1.2 to 2% by mass, and even more preferably 1.2 to 1.5% by mass.

(Oxidizing Agent)

The polishing liquid of the present embodiment may contain an oxidizing agent (for example, potassium periodate, ammonium persulfate, hypochlorous acid, ozone water, or the like), but preferably, the polishing liquid of the present embodiment does not contain an oxidizing agent. That is, the content of the oxidizing agent in the polishing liquid is preferably 0.0001% by mass or less based on the total mass of the polishing liquid. The content of the oxidizing agent other than hydrogen peroxide can be measured, for example, potentiometric titration. Equipment, reagents, and the like used in the potentiometric titration may be appropriately adjusted depending on the type of the oxidizing agent.

(pH of Polishing Liquid)

The pH of the polishing liquid of the present embodiment is 6.0 or more. As described above, in a case where the pH is 6.0 or more, a variation in polishing rate of Co tends to occur. On the other hand, in the present embodiment, from the reasons that the pH of the polishing liquid is 6.0 or more, the content of the hydrogen peroxide is 0.0001% by mass or less, and the like, the Co-containing portion to be polished can be polished at a stable polishing rate. Further, when the pH is 6 or more, occurrence of corrosion in the Co-containing portion to be polished can be suppressed.

From the viewpoint that the Co-containing portion to be polished can be polished at a more stable polishing rate and the viewpoint that corrosion of the Co-containing portion to be polished can be further suppressed, the pH of the polishing liquid is preferably 7.0 or more and more preferably 8.0 or more. In a case where an article to be polished includes a portion to be polished containing silicon and the abrasive particles contain silica, from the viewpoints of suppressing the dissolution of the portion to be polished and the abrasive particles and easily obtaining a stable polishing rate, the pH of the polishing liquid is preferably 12.0 or less, more preferably 11.5 or less, and further preferably 11.0 or less. From these viewpoints, the pH of the polishing liquid is preferably 6.0 to 12.0, more preferably 7.0 to 11.5, and further preferably 8.0 to 11.0. Incidentally, in a case where the polishing liquid contains hydrogen peroxide, as the pH increases, the hydrogen peroxide tends to be dissolved over time, and the content of the hydrogen peroxide tends to decrease. Therefore, as the pH of the polishing liquid increases, the effect of the present invention tends to be more significantly exhibited.

The pH of the polishing liquid is measured by a pH meter (for example, Model F-51 manufactured by HORIBA, Ltd.). Specifically, the pH is measured by placing an electrode in the polishing liquid after 3-point calibration using standard buffer solution (phthalate pH buffer solution, pH: 4.01 (25° C.), neutral phosphate pH buffer solution, pH: 6.86 (25° C.), borate pH buffer solution, pH: 9.18 (25° C.)) and measuring the value upon stabilization after an elapse of 3 minutes or longer, and the obtained measurement value can be used as the pH of the polishing liquid.

The polishing liquid of the present embodiment described above is prepared as a stock solution for a polishing liquid in some cases. The stock solution for a polishing liquid is diluted with a liquid medium such as water to provide the polishing liquid of the present embodiment. The stock solution for a polishing liquid is stored in such a state that the amount of the liquid medium is more reduced than that during use, and is used by being diluted with the liquid medium before use or during use. According to this, the cost, space, and the like which are necessary for transportation, storage, and the like of the polishing liquid can be reduced. The stock solution for a polishing liquid and the polishing liquid of the present embodiment are different in that the content of the liquid medium in the stock solution for a polishing liquid is smaller than the content of the liquid medium in the polishing liquid of the present embodiment. The stock solution for a polishing liquid may be used as the polishing liquid by being diluted with the liquid medium immediately before polishing, or the stock solution and the liquid medium may be supplied onto the polishing platen and then the polishing liquid may be prepared on the polishing platen. The dilution ratio of the stock solution is, for example, 1.5 times or more.

### EXAMPLES

Hereinafter, the present invention will be described in detail with reference to Examples, but the present invention is not limited to these Examples unless deviating from the technical idea of the present invention. For example, polishing liquid compositions, polishing conditions, and films to be polished may not be as described in the present Examples.

(Preparation of Abrasive Particles)

As the abrasive particles, silica particles having an average secondary particle diameter of 65 nm (silica A) and silica particles having an average secondary particle diameter of 28 nm (silica B) were prepared. The average secondary particle diameters of the silica A and the silica B were measured by a photon correlation method using particle size distribution N5 manufactured by Beckman Coulter, Inc. Specifically, an aqueous dispersion of silica particles was diluted with water so that the scattering intensity became 5.0×10⁴ to 1.0×10⁶ cps to thereby obtain a measurement sample, and the measurement sample was placed in a plastic cell and the average secondary particle diameter was measured.

<Preparation of Evaluation Substrate>

The following substrates were prepared as first to third evaluation substrates.
First evaluation substrate: a substrate obtained by forming a film made of cobalt (Co) having a thickness of 200 nm on a silicon substrate (wafer with a diameter of 12 inch)
Second evaluation substrate: a substrate obtained by forming a film made of titanium nitride (TiN) having a thickness of 200 nm on a silicon substrate (wafer with a diameter of 12 inch)
Third evaluation substrate: a substrate obtained by forming a film made of silicon dioxide (TEOS) having a thickness of 1,000 nm on a silicon substrate (wafer with a diameter of 12 inch)

### Examples 1 and 2 and Comparative Examples 1 to 8

(Preparation of Polishing Liquid)

Polishing liquids of Examples 1 and 2 and Comparative Examples 1 to 8 were prepared using respective components shown in Tables 1 and 2, and as necessary, a pH adjusting agent (48%-KOH aqueous solution). Specifically, components other than the abrasive particles were added to deionized water and stirred. Next, the abrasive particles were added to the obtained mixture and stirred, thereby preparing a polishing liquid. The blending amounts of the respective components shown in Tables 1 and 2 were adjusted so that the content of each component in the obtained polishing liquid (the content based on the total mass of the polishing liquid, unit: % by mass) became a value shown in Table 1 or 2. Further, in the case of using a pH adjusting agent, the blending amount of the pH adjusting agent was adjusted so that the pH of the polishing liquid became a value shown in Table 1 or 2. In Example 1 and Example 2, hydrogen peroxide was not used.

(Measurement of pH)

The pH of each polishing liquid was measured according to the following.
Measurement temperature: 25° C.
Measuring instrument: pH meter (“Model F-51” manufactured by HORIBA, Ltd.
Measurement method: The pH was measured by placing an electrode in the polishing liquid after 3-point calibration using standard buffer solution (phthalate pH buffer solution, pH: 4.01 (25° C.), neutral phosphate pH buffer solution, pH: 6.86 (25° C.), borate pH buffer solution, pH: 9.18 (25° C.)) and measuring the value upon stabilization after an elapse of 3 minutes or longer.

(Polishing of Substrate)

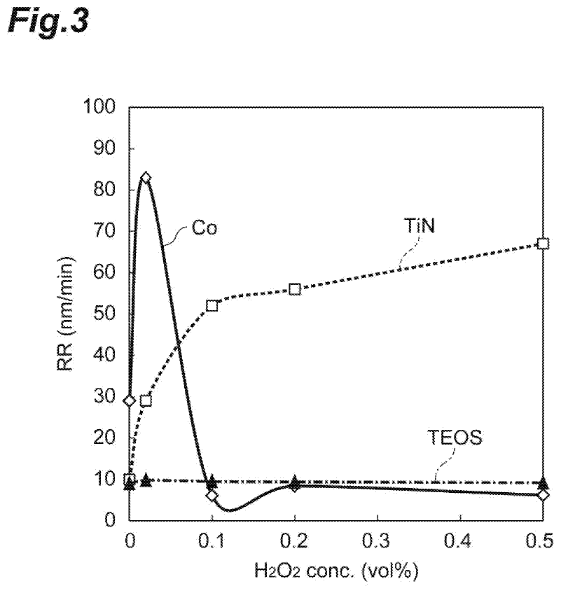

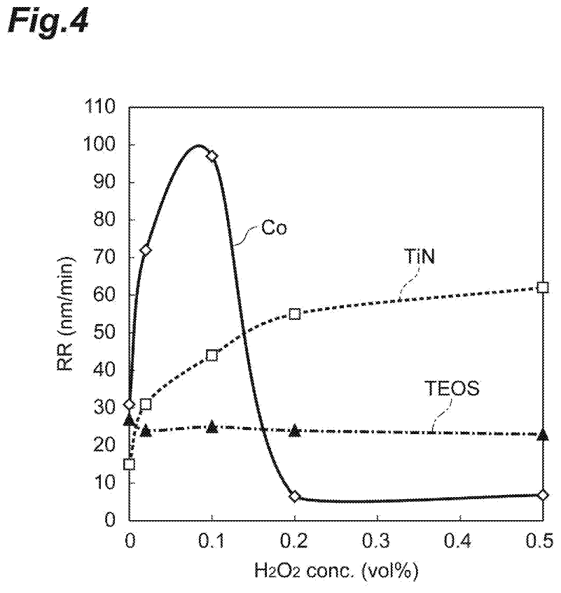

The films (the film made of Co, the film made of TiN, and the film made of TEOS) on the first to third evaluation substrates were polished using each polishing liquid under the following polishing conditions, and the polishing rate of Co, the polishing rate of TiN, and the polishing rate of TEOS were measured. Electrical resistance values before and after polishing were measured using a resistance measuring device VR-120/08S (manufactured by Hitachi Kokusai Electric Inc.), a difference in thickness before and after polishing was obtained by a converting method from the measured electrical resistance values, and a polishing rate was obtained by dividing the film thickness difference by a polishing time. The results are shown in Table 1 and FIG. 3, and Table 2 and FIG. 4. Incidentally, FIGS. 3 to 7 are graphs showing a relation between a hydrogen peroxide concentration in a polishing liquid and a polishing rate, the horizontal axis in FIGS. 3 to 7 represents a content of hydrogen peroxide (H₂O₂), and the vertical axis in FIGS. 3 to 7 represents a polishing rate (RR: removal rate).
Polishing machine: polishing machine for single side (F-REX300 manufactured by EBARA CORPORATION)
Polishing pad: H800 (manufactured by Fujibo Holdings, Inc.)
Polishing pressure: 10.3 kPa
Number of revolutions of platen: 93 rpm
Number of revolutions of head: 87 rpm
Amount of polishing liquid to be supplied: 250 ml/min
Polishing time:

polishing time of film made of Co and film made of TiN: 30 seconds

polishing time of film made of TEOS: 60 seconds

TABLE 1

| | | | Comparative | Comparative | Comparative | Comparative |
|---|---|---|---|---|---|---|
| | | Example 1 | Example 1 | Example 2 | Example 3 | Example 4 |
| Polishing | Silica A | 1.5 | 1.5 | 1.5 | 1.5 | 1.5 |
| liquid | Malonic acid | 0.08 | 0.08 | 0.08 | 0.08 | 0.08 |
| | Benzotriazole | 0.005 | 0.005 | 0.005 | 0.005 | 0.005 |
| | H₂O₂ | 0.00 | 0.02 | 0.10 | 0.20 | 0.50 |
| | pH | 10 | 10 | 10 | 10 | 10 |
| Polishing | Co | 29 | 83 | 6.1 | 8.4 | 6.2 |
| rate | TiN | 10 | 29 | 52 | 56 | 67 |
| (nm/min) | TEOS | 9 | 9.8 | 9.5 | 9.4 | 9.2 |

TABLE 2

| | | | Comparative | Comparative | Comparative | Comparative |
|---|---|---|---|---|---|---|
| | | Example 2 | Example 5 | Example 6 | Example 7 | Example 8 |
| Polishing | Silica B | 7.0 | 7.0 | 7.0 | 7.0 | 7.0 |
| liquid | Citric acid | 0.40 | 0.40 | 0.40 | 0.40 | 0.40 |
| | Benzotriazole | 0.010 | 0.010 | 0.010 | 0.010 | 0.010 |
| | Polyoxyethylene | 0.003 | 0.003 | 0.003 | 0.003 | 0.003 |
| | lauryl ether | | | | | |
| | H₂O₂ | 0.00 | 0.02 | 0.10 | 0.20 | 0.50 |
| | pH | 9.5 | 9.5 | 9.5 | 9.5 | 9.5 |
| Polishing | Co | 31 | 72 | 97 | 6.5 | 6.8 |
| rate | TiN | 15 | 31 | 44 | 55 | 62 |
| (nm/min) | TEOS | 27 | 24 | 25 | 24 | 23 |

### Examples 3 and 4 and Comparative Examples 9 to 16

Polishing liquids of Examples 3 and 4 and Comparative Examples 9 to 16 were prepared in the same manner as in Example 1, except that instead of the respective components shown in Table 1, respective components shown in Table 3 or 4 were blended so that the content of each component in the obtained polishing liquid (the content based on the total mass of the polishing liquid, unit: % by mass) became a value shown in Table 3 or 4, and as necessary, a pH adjusting agent (48%-KOH aqueous solution) was further blended so that the pH of the polishing liquid became a value shown in Table 3 or 4. The pH of each polishing liquid was measured by the same method as in Example 1. Incidentally, in Examples 3 and 4, hydrogen peroxide was not used.

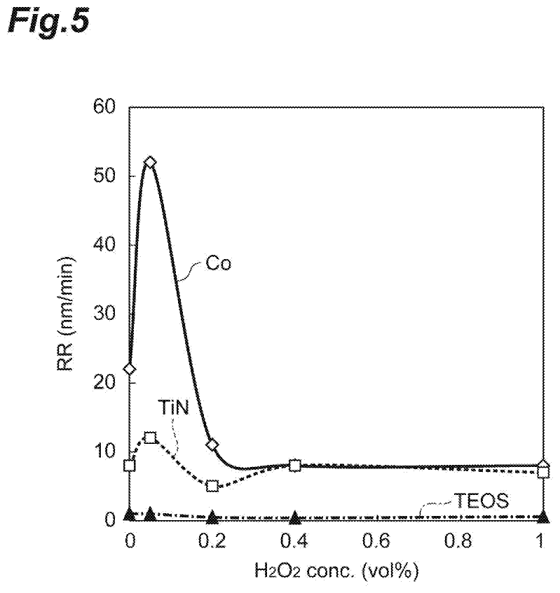

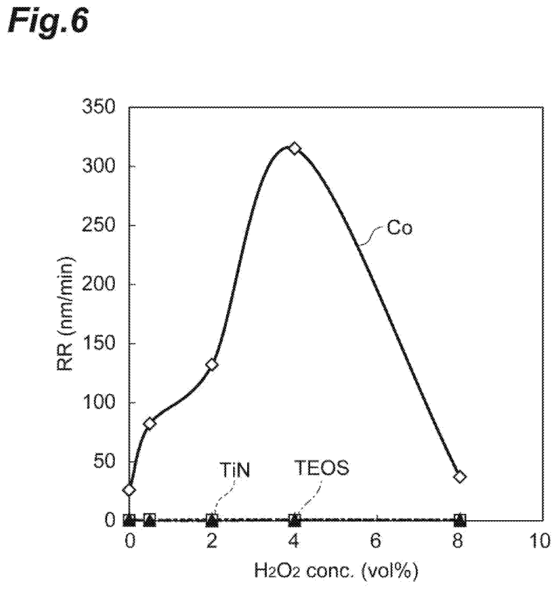

The first to third evaluation substrates used in Example 1 were prepared, the film made of Co, the film made of TiN, and the film made of TEOS were polished in the same manner as in Example 1, except that each of the polishing liquids of Examples 3 and 4 and Comparative Examples 9 to 16 was used instead of the polishing liquid of Example 1 and the polishing conditions were changed as follows, and the polishing rate of Co, the polishing rate of TiN, and the polishing rate of TEOS were obtained. The results are shown in Table 3 and FIG. 5, and Table 4 and FIG. 6.
Polishing machine: polishing machine for single side (Reflexion LK manufactured by Applied Materials, Inc.)
Polishing pad: IC1010 (manufactured by Nitta Haas Incorporated)
Polishing pressure: 6.9 kPa
Number of revolutions of platen: 93 rpm
Number of revolutions of head: 87 rpm
Amount of polishing liquid to be supplied: 300 ml/min
Polishing time:

polishing time of film made of Co and film made of TiN: 30 seconds

polishing time of film made of TEOS: 60 seconds

TABLE 3

| | | | Comparative | Comparative | Comparative | Comparative |
|---|---|---|---|---|---|---|
| | | Example 3 | Example 9 | Example 10 | Example 11 | Example 12 |
| Polishing | Silica B | 1.0 | 1.0 | 1.0 | 1.0 | 1.0 |
| liquid | Glycine | 0.55 | 0.55 | 0.55 | 0.55 | 0.55 |
| | Arginine | 0.20 | 0.20 | 0.20 | 0.20 | 0.20 |
| | Benzotriazole | 0.080 | 0.080 | 0.080 | 0.080 | 0.080 |
| | 3-Methoxy-3-methylbutanol | 0.50 | 0.50 | 0.50 | 0.50 | 0.50 |
| | H₂O₂ | 0.00 | 0.05 | 0.20 | 0.40 | 1.00 |
| | pH | 8.5 | 8.5 | 8.5 | 8.5 | 8.5 |
| Polishing | Co | 22 | 52 | 11 | 8 | 8 |
| rate | TiN | 8 | 12 | 5 | 8 | 7 |
| (nm/min) | TEOS | 1 | 1 | 0.5 | 0.4 | 0.6 |

TABLE 4

| | | | Comparative | Comparative | Comparative | Comparative |
|---|---|---|---|---|---|---|
| | | Example 4 | Example 13 | Example 14 | Example 15 | Example 16 |
| Polishing | Silica A | 1.0 | 1.0 | 1.0 | 1.0 | 1.0 |
| liquid | Glycine | 1 | 1 | 1 | 1 | 1 |
| | Benzotriazole | 0.10 | 0.10 | 0.10 | 0.10 | 0.10 |
| | 3-Methoxy-3-methylbutanol | 0.50 | 0.50 | 0.50 | 0.50 | 0.50 |
| | H₂O₂ | 0.00 | 0.50 | 2.00 | 4.00 | 8.00 |
| | pH | 6.0 | 6.0 | 6.0 | 6.0 | 6.0 |
| Polishing | Co | 26 | 82 | 132 | 315 | 37 |
| rate | TiN | 0.4 | 0.5 | 1 | 0.9 | 0.8 |
| (nm/min) | TEOS | 0.9 | 0.4 | 0.3 | 0.6 | 0.5 |

### Comparative Examples 17 to 21

Polishing liquids of Comparative Examples 17 to 21 were prepared in the same manner as in Example 1, except that instead of the respective components shown in Table 1, respective components shown in Table 5 were blended so that the content of each component in the obtained polishing liquid (the content based on the total mass of the polishing liquid, unit: % by mass) became a value shown in Table 5, and as necessary, a pH adjusting agent (48%-KOH aqueous solution) was further blended so that the pH of the polishing liquid became a value shown in Table 5. The pH of each polishing liquid was measured by the same method as in Example 1. Incidentally, in Comparative Example 17, hydrogen peroxide was not used.

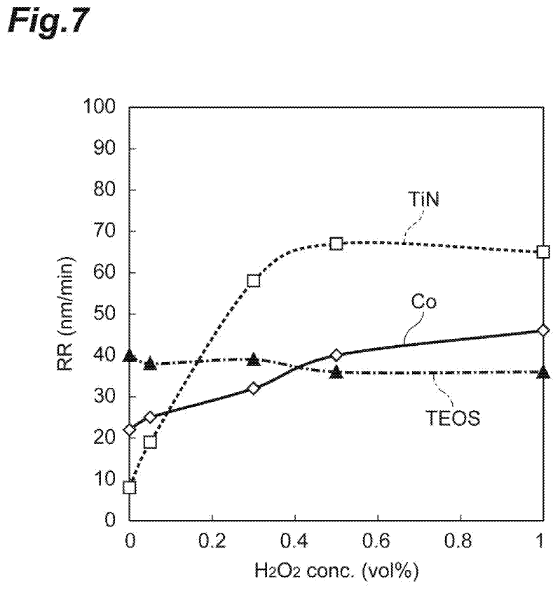

The first to third evaluation substrates used in Example 1 were prepared, the film made of Co, the film made of TiN, and the film made of TEOS were polished in the same manner as in Example 1, except that each of the polishing liquids of Comparative Examples 17 to 21 was used instead of the polishing liquid of Example 1, and the polishing conditions were changed as follows, and the polishing rate of Co, the polishing rate of TiN, and the polishing rate of TEOS were obtained. The results are shown in Table 5 and FIG. 7.
Polishing machine: polishing machine for single side (Reflexion LK manufactured by Applied Materials, Inc.)
Polishing pad: VP3100 (manufactured by Nitta Haas Incorporated)
Polishing pressure: 10.3 kPa
Number of revolutions of platen: 93 rpm
Number of revolutions of head: 87 rpm
Amount of polishing liquid to be supplied: 250 ml/min
Polishing time:

polishing time of film made of Co and film made of TiN: 30 seconds

polishing time of film made of TEOS: 60 seconds

TABLE 5

| | | Comparative | Comparative | Comparative | Comparative | Comparative |
|---|---|---|---|---|---|---|
| | | Example 17 | Example 18 | Example 19 | Example 20 | Example 21 |
| Polishing | Silica A | 1.0 | 1.0 | 1.0 | 1.0 | 1.0 |
| liquid | Citric acid | 0.005 | 0.005 | 0.005 | 0.005 | 0.005 |
| | Benzotriazole | 0.100 | 0.100 | 0.100 | 0.100 | 0.100 |
| | 3-Methoxy-3-methylbutanol | 4.00 | 4.00 | 4.00 | 4.00 | 4.00 |
| | H₂O₂ | 0.00 | 0.05 | 0.30 | 0.50 | 1.00 |
| | pH | 3.5 | 3.5 | 3.5 | 3.5 | 3.5 |
| Polishing | Co | 22 | 25 | 32 | 40 | 46 |
| rate | TiN | 8 | 19 | 58 | 67 | 65 |
| (nm/min) | TEOS | 40 | 38 | 39 | 36 | 36 |

From the results of Example 1 and Comparative Examples 1 to 4 using the polishing liquid having a pH of 10, it is found that the polishing rate of Co is greatly changed by a slight difference in hydrogen peroxide concentration in a case where the pH of the polishing liquid is 10 (see FIG. 3). From the results of Example 2 and Comparative Examples 5 to 8 using the polishing liquid having a pH of 9.5, Example 3 and Comparative Examples 9 to 12 using the polishing liquid having a pH of 8.5, and Example 4 and Comparative Examples 13 to 16 using the polishing liquid having a pH of 6.0, it is found that the same tendency is shown even in a case where the pHs of the polishing liquid are 9.5, 8.5, and 6.0 (see FIGS. 4 to 6). On the other hand, in a case where the pH of the polishing liquid is 3.5, a change amount of the polishing rate of Co with respect to the change of the hydrogen peroxide concentration (see FIG. 7) was clearly smaller than a change amount of the polishing rate of Co with respect to the change of the hydrogen peroxide concentration in a case where the pH of the polishing liquid is 6 or more (see FIGS. 3 to 6).

From the above results, it became clear that in a case where hydrogen peroxide is mixed with the polishing liquid having a pH of 6.0 or more and 12.0 or less and containing water, abrasive particles, and a metal dissolving agent and then used, the polishing rate of Co is greatly changed by the change in content of the hydrogen peroxide. In Examples described above, by using the polishing liquid without hydrogen peroxide being mixed, it was possible to obtain a stable polishing rate of Co without depending on a slight change in content of the hydrogen peroxide.

### Reference Examples 1 to 3

(Preparation of Polishing Liquid)

Glycine and hydrogen peroxide (H₂O₂) were added to deionized water and stirred. Next, the silica A was added to the obtained mixture and stirred, thereby preparing a polishing liquid of Reference Example 1. The blending amounts of glycine, hydrogen peroxide, and the silica A were adjusted so that the contents of the respective components in the obtained polishing liquid (the contents based on the total mass of the polishing liquid, unit: % by mass) became 0.5% by mass, 1.0% by mass, and 1.0% by mass, respectively.

Further, a 48%-KOH aqueous solution was gradually added to the obtained polishing liquid of Reference Example 1 to obtain polishing liquids of Reference Example 2 and Reference Example 3. In Reference Example 2 and Reference Example 3, a 48%-KOH aqueous solution was added so that the pHs became values shown in Table 6, respectively. The pH of each polishing liquid was measured by the same method as in Example 1.

(Stability Evaluation of Hydrogen Peroxide Concentration)

For the polishing liquids of Reference Examples 1 to 3, immediately after the preparation of the polishing liquid and after the polishing liquid was left to stand still for 7 days under the condition of 25° C., the hydrogen peroxide concentration in the polishing liquid was measured using a potentiometric automatic titrator COM2500 manufactured by HIRANUMA SANGYO Co., Ltd., a change amount in hydrogen peroxide concentration over time was obtained, and thus the stability of the hydrogen peroxide concentration (the content of hydrogen peroxide) in the polishing liquid was evaluated. Specifically, first, hexaammonium heptamolybdate tetrahydrate was added to 10% by mass of sulfuric acid aqueous solution so that the concentration after mixing became 0.05% by mass to prepare a mixed liquid A, and about 0.5 g of the mixed liquid A was added to about 1.0 g of the polishing liquid (polishing liquids of Reference Examples 1 to 3) to obtain a mixed liquid B. Then, a mixed liquid C obtained by mixing about 5.0 g of potassium iodide (1.0 mol/L) and about 30 g of pure water was added to the mixed liquid B to obtain a red evaluation solution. The evaluation solution was titrated using a sodium thiosulfate aqueous solution with a factor of 1.0 (0.01 mol/L) as a volumetric solution. The hydrogen peroxide concentration in the polishing liquid was obtained from the titer of the sodium thiosulfate aqueous solution. The results are shown in Table 6.

TABLE 6

| | | Reference | Reference | Reference |
|---|---|---|---|---|
| | | Example 1 | Example 2 | Example 3 |
| Polishing | Silica A | 1.0 | 1.0 | 1.0 |
| liquid | Glycine | 0.5 | 0.5 | 0.5 |
| | H₂O₂ | 1.00 | 1.00 | 1.00 |
| | pH | 3.5 | 6 | 10 |
| H₂O₂ | Immediately after | 1.00 | 1.00 | 1.00 |
| concentration | preparation | | | |
| | After 7 days | 1.00 | 1.00 | 0.74 |
| | Change amount | 0.00 | 0.00 | 0.26 |
| | over time | | | |

From the results shown in Table 6, a change in hydrogen peroxide concentration was not observed in Reference Example 1 with a pH of 3.5 and Reference Example 2 with a pH of 6.0, but a decrease in hydrogen peroxide concentration over time was observed in Reference Example 3 with a pH of 10. From the above results, it became clear that a decrease in hydrogen peroxide concentration may be a problem in a case where the pH of the polishing liquid containing water, abrasive particles, and a metal dissolving agent is in an alkaline region. As shown in the evaluation results of the polishing rate, although a change in hydrogen peroxide concentration greatly influences the polishing rate of Co, since there is no influence of a decrease in hydrogen peroxide over time in the polishing method of the present invention using a polishing liquid substantially not containing hydrogen peroxide (the hydrogen peroxide concentration is 0.0001% by mass or less), it can be said that the Co-containing surface to be polished can be polished at a stable polishing rate.

### Reference Examples 4 to 9

(Preparation of Polishing Liquid)

Malic acid, glycine, benzotriazole, 3-methoxy-3-methylbutanol, and hydrogen peroxide were added to deionized water and stirred. Next, the silica A was added to the obtained mixture and stirred, thereby preparing a polishing liquid of Reference Example 4. The blending amounts of malic acid, glycine, benzotriazole, 3-methoxy-3-methylbutanol, hydrogen peroxide, and the silica A were adjusted so that the contents of the respective components in the obtained polishing liquid (the contents based on the total mass of the polishing liquid, unit: % by mass) became 0.3% by mass, 1.0% by mass, 0.050% by mass, 0.30% by mass, 0.90% by mass, and 0.1% by mass, respectively.

Further, a 48%-KOH aqueous solution was gradually added to the obtained polishing liquid of Reference Example 4 to obtain polishing liquids of Reference Examples 5 to 9. In Reference Examples 5 to 9, a 48%-KOH aqueous solution was added so that the pHs became values shown in Table 7, respectively. The pH of each polishing liquid was measured by the same method as in Example 1.

(Evaluation Method of Corrosion Rate of Co)

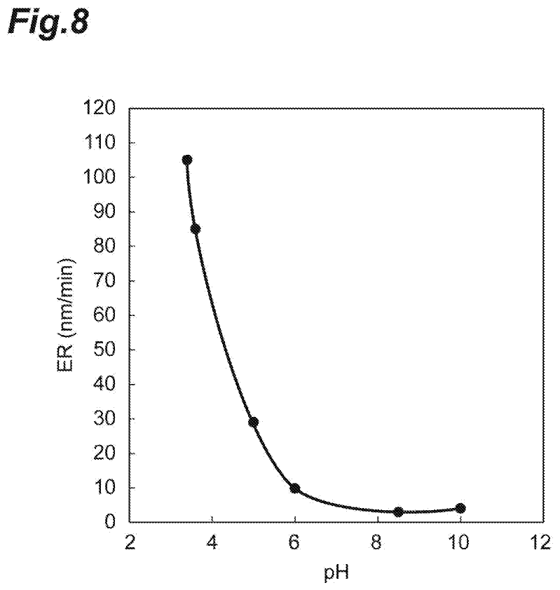

The corrosion rate of Co was evaluated by the following procedures using the polishing liquids of Reference Examples 4 to 9. First, the first evaluation substrate was cut into 2 cm square to prepare an evaluation substrate. Next, the evaluation substrate was attached to a stirring spring, and the evaluation substrate was immersed in the polishing liquid warmed to 60° C. for 5 minutes while the stirring spring to which the evaluation substrate is attached is rotated at 200 rpm. The corrosion rate was calculated from a difference in thickness of the evaluation substrate before and after immersion and the immersion time. The results are shown in Table 7 and FIG. 8. FIG. 8 is a graph showing a change amount of a corrosion rate of Co with respect to pH, the horizontal axis in FIG. 8 represents a pH of a polishing liquid used in evaluation, and the vertical axis represents a corrosion rate of Co (ER: etching rate).

TABLE 7

| | | Reference | Reference | Reference | Reference | Reference | Reference |
|---|---|---|---|---|---|---|---|
| | | Example 4 | Example 5 | Example 6 | Example 7 | Example 8 | Example 9 |
| Polishing | Silica A | 0.1 | 0.1 | 0.1 | 0.1 | 0.1 | 0.1 |
| liquid | Malic acid | 0.3 | 0.3 | 0.3 | 0.3 | 0.3 | 0.3 |
| | Glycine | 1.0 | 1.0 | 1.0 | 1.0 | 1.0 | 1.0 |
| | Benzotriazole | 0.050 | 0.050 | 0.050 | 0.050 | 0.050 | 0.050 |
| | 3-Methoxy-3-methylbutanol | 0.30 | 0.30 | 0.30 | 0.30 | 0.30 | 0.30 |
| | H₂O₂ | 0.90 | 0.90 | 0.90 | 0.90 | 0.90 | 0.90 |
| | pH | 3.4 | 3.6 | 5 | 6 | 8.5 | 10 |

| | | | | | | |
|---|---|---|---|---|---|---|
| Corrosion rate of Co (nm/min) | 105 | 85 | 29 | 9.8 | 3 | 4 |

As shown in Table 7 and FIG. 8, it was observed at around pH 6.0 that, as the pH decreases, the corrosion rate of Co decreases, and as the pH increases, the corrosion rate of Co decreases. From the above results, it became clear that the pH of the polishing liquid is greatly involved with the corrosion rate of Co, and the corrosion rate of Co is easy to suppress when the pH of the polishing liquid containing water, abrasive particles, and a metal dissolving agent is 6 or more.

### REFERENCE SIGNS LIST

1a, 11a: article, 2, 12: substrate, 3, 13: insulating portion, 3a: groove portion, 4: Ti-containing portion to be polished (first portion to be polished), 5: Co-containing portion to be polished (second portion to be polished), 6: Cu-containing portion to be polished (third portion to be polished), 7: first liner portion, 8: second liner portion, 9: wiring portion, 14: first portion to be polished, 15: second portion to be polished, 16: liner portion, 17: wiring portion.

1. A method for polishing an article including a Co-containing portion to be polished by a polishing liquid, wherein
the polishing liquid contains water, abrasive particles, and a metal dissolving agent,
a pH of the polishing liquid is 6.0 or more, and
a content of hydrogen peroxide in the polishing liquid is 0.0001% by mass or less based on the total mass of the polishing liquid.

2. The method for polishing according to claim 1, wherein the metal dissolving agent is an organic acid.

3. The method for polishing according to claim 1, wherein the metal dissolving agent contains at least one selected from the group consisting of dicarboxylic acids and amino acids.

4. The method for polishing according to claim 1, wherein a content of the abrasive particles is 0.01 to 20% by mass based on the total mass of the polishing liquid.

5. The method for polishing according to claim 1, wherein the abrasive particles contain silica.

6. The method for polishing according to claim 1, wherein the polishing liquid further contains a metal corrosion inhibitor.

7. The method for polishing according to claim 1, wherein the polishing liquid further contains a water-soluble polymer.

8. The method for polishing according to claim 1, wherein the polishing liquid further contains a pH adjusting agent.

9. A polishing liquid used for polishing an article including a Co-containing portion to be polished, the polishing liquid comprising:
water; abrasive particles; and a metal dissolving agent, wherein
a pH of the polishing liquid is 6.0 or more, and
a content of hydrogen peroxide is 0.0001% by mass or less based on the total mass of the polishing liquid.
